(19) United States
(12) Patent Application Publication
(10) Pub. No.: US 2025/0081567 A1
(43) Pub. Date: Mar. 6, 2025

(54) GALLIUM OXIDE SEMICONDUCTOR DEVICE WITH ENHANCED OHMIC CONTACT PROPERTY AND METHOD OF MANUFACTURING THE SAME

(71) Applicant: POWER CUBESEMI INC., Seongnam-si (KR)

(72) Inventors: Tai Young KANG, Gwangju-si (KR); Sin Su KYOUNG, Hanam-si (KR); Yu Sup JUNG, Osan-si (KR)

(73) Assignee: POWER CUBESEMI INC., Seongnam-si (KR)

(21) Appl. No.: 18/821,105

(22) Filed: Aug. 30, 2024

(30) Foreign Application Priority Data
Aug. 30, 2023 (KR) 10-2023-0114811

(51) Int. Cl. H01L 29/24; H01L 21/02; H01L 21/477; H01L 29/49

(52) U.S. Cl. CPC H10D 62/80; H01L 21/02565; H01L 21/02576; H01L 21/477; H10D 64/667

(57) ABSTRACT

Gallium oxide semiconductor device may include an n-type gallium oxide epitaxial layer epitaxially grown on a gallium oxide substrate, an n-type contact layer formed of indium tin oxide on the n-type gallium oxide epitaxial layer, a metal electrode layer formed on the n-type contact layer, and a diffusion layer extending from a heterojunction between the n-type gallium oxide epitaxial layer and the n-type contact layer toward the n-type gallium oxide epitaxial layer. The diffusion layer may be formed by diffusing the n-type contact layer into the n-type gallium oxide epitaxial layer by a post-annealing.

### CROSS-REFERENCE TO RELATED APPLICATION

The present application claims priority under 35 U.S.C. § 119 (a) to Korean application number 10-2023-0114811, filed on Aug. 30, 2023, in the Korean Intellectual Property Office, which is incorporated herein by reference in its entirety.

### BACKGROUND

The present invention relates to a lateral gallium oxide transistor.

Due to the rapid developments of the power, automotive electronics and home appliance industries, the demand for high-performance power semiconductor devices has exploded. Due to ongoing research, ultra-wideband semiconductors including silicon carbide and gallium nitride have achieved higher performance than silicon-based power semiconductors. However, they have the disadvantages of difficult bulk single crystal growth and high production costs.

Gallium oxide is an emerging ultra-wideband semiconductor material after silicon carbide and gallium nitride, with a bandgap of about 4.7 to about 4.9 eV, far beyond the bandgap width of silicon carbide and gallium nitride, and a theoretical breakdown field of 8 MV/cm. Gallium oxide is particularly capable of growing substrates and epitaxial layers at relatively low cost compared to other ultra-wideband semiconductor materials. However, because the effective hole mass of an appropriate p-type dopant is large and the acceptor activation energy is high, it is difficult to implement a pn homojunction-based β-Ga₂O₃ device.

### SUMMARY

According to one aspect of the present disclosure, there is provided a gallium oxide semiconductor device. The gallium oxide semiconductor device may include an n-type gallium oxide epitaxial layer epitaxially grown on a gallium oxide substrate, an n-type contact layer formed of indium tin oxide on the n-type gallium oxide epitaxial layer, a metal electrode layer formed on the n-type contact layer, and a diffusion layer extending from a heterojunction between the n-type gallium oxide epitaxial layer and the n-type contact layer toward the n-type gallium oxide epitaxial layer. The diffusion layer may be formed by diffusing the n-type contact layer into the n-type gallium oxide epitaxial layer by a post-annealing.

In one embodiment, the n-type contact layer has a thickness of 10 nm to 30 nm.

In one embodiment, a post-annealing temperature is in a range between 700° C. and 800° C.

In one embodiment, the gallium oxide semiconductor device may further include an insulating layer defining a gate region and an electrode region on the n-type gallium oxide epitaxial layer, a p-type nickel oxide layer deposited on the gate region, a dielectric layer deposited on the p-type nickel oxide layer, and a gate electrode layer deposited on the dielectric layer. The n-type contact layer may be formed in the electrode region.

In one embodiment, the gallium oxide semiconductor device may further include a diffusion barrier layer, interposed between the n-type gallium oxide epitaxial layer exposed in the gate region and the p-type nickel oxide layer.

In one embodiment, the diffusion barrier layer may be formed by depositing aluminum oxide in a thickness of 2 Å to 50 Å.

In one embodiment, the gallium oxide semiconductor device may further include a counter doped region formed within the n-type gallium oxide epitaxial layer below the diffusion barrier layer and having a lower concentration than the n-type gallium oxide epitaxial layer.

In one embodiment, the diffusion barrier layer may have an opening exposing the n-type gallium oxide epitaxial layer, wherein the counter doped region is formed by nickel diffusing from the p-type nickel oxide layer through the opening into the n-type gallium oxide epitaxial layer.

According to another aspect of the present disclosure, there is provided a method of manufacturing gallium oxide semiconductor device, including forming an n-type contact layer of indium tin oxide on an n-type gallium oxide epitaxial layer epitaxially grown on an n-type gallium oxide substrate, forming a metal electrode layer on the n-type contact layer, and forming a diffusion layer extending from a heterojunction between the n-type gallium oxide epitaxial layer and the n-type contact layer toward the n-type gallium oxide epitaxial layer by a post-annealing.

In one embodiment, the forming an n-type contact layer of indium tin oxide on an n-type gallium oxide epitaxial layer epitaxially grown on an n-type gallium oxide substrate may include forming an insulating layer defining a gate region and an electrode region on the n-type gallium oxide epitaxial layer, depositing a diffusion barrier layer on the n-type gallium oxide epitaxial layer exposed in the gate region, depositing a p-type nickel oxide layer on the diffusion barrier layer, depositing a dielectric layer on the p-type nickel oxide layer, depositing a gate electrode layer on the dielectric laye; and forming the n-type contact layer on the n-type gallium oxide epitaxial layer exposed in the electrode region.

In one embodiment, the diffusion barrier layer may be deposited at a thickness such that a pn heterojunction is formed between the p-type nickel oxide layer and the n-type gallium oxide epitaxial layer while preventing nickel diffusion from the p-type nickel oxide layer to the n-type gallium oxide epitaxial layer.

In one embodiment, the method may further include forming an opening exposing the n-type gallium oxide epitaxial layer in the diffusion barrier layer.

### BRIEF DESCRIPTION OF DRAWINGS

Hereinafter, embodiments of the invention will be described with reference to the accompanying drawings. For the purpose of easy understanding of the invention, the same elements will be referred to by the same reference signs. Configurations illustrated in the drawings are examples for describing the invention, and do not restrict the scope of the invention. Particularly, in the drawings, some elements are slightly exaggerated for the purpose of easy understanding of the invention. Since the drawings are used to easily understand the invention, it should be noted that widths, depths, and the like of elements illustrated in the drawings might change at the time of actual implementation thereof. Meanwhile, throughout the detailed description of the invention, the same components are described with reference to the same reference numerals.

FIG. 1a and FIG. 1b exemplarily illustrate change in channel properties caused by nickel oxide;

FIG. 2 exemplarily illustrate change in channel properties caused by nickel oxide after gate is formed;

FIG. 3 exemplarily illustrates a gallium oxide semiconductor device;

FIG. 4A, FIG. 4B, FIG. 4C, FIG. 4D, FIG. 4E, FIG. 4F, FIG. 4G, FIG. 4H and FIG. 4I exemplarily illustrate a process for manufacturing the gallium oxide semiconductor device;

FIG. 5A and FIG. 5B show the electrical characteristics of the gallium oxide semiconductor device;

FIG. 6 exemplarily illustrates a gallium oxide semiconductor device modified from the gallium oxide semiconductor device in FIG. 3;

FIG. 7A, FIG. 7B, FIG. 7C and FIG. 7D exemplarily illustrate a process for manufacturing the gallium oxide semiconductor device shown in FIG. 6;

FIG. 8 exemplarily illustrates a gallium oxide semiconductor device further modified from the gallium oxide semiconductor device in FIG. 3;

FIG. 9A, FIG. 9B, FIG. 9C and FIG. 9D exemplarily illustrate a process for manufacturing the gallium oxide semiconductor device shown in FIG. 8;

FIG. 10A, FIG. 10B, FIG. 10C and FIG. 10D exemplarily illustrate an alternative process for manufacturing the gallium oxide semiconductor device shown in FIG. 8;

FIG. 11 exemplarily illustrates adjusting the sidewall slope of a recessed gate trench;

FIG. 12 exemplarily illustrates the operation of a gallium oxide semiconductor device according to gate voltage;

FIG. 13 is a graph illustrating the electrical characteristics of nickel oxide according to oxygen flow rate;

FIG. 14 exemplarily illustrates a gallium oxide semiconductor device still further modified from the gallium oxide semiconductor device in FIG. 3;

FIG. 15 is a graph showing SIMS results for the source/drain electrode structure illustrated in FIG. 14;

FIG. 16 exemplarily illustrates a sample for measuring changes in ohmic contact resistance occurred by the diffusion layer;

FIG. 17A and FIG. 17B are graphs illustrating the current-voltage measured in samples with the n-type contact layer having a thickness of 300 nm;

FIG. 18A, FIG. 18B, FIG. 18C, FIG. 18D and FIG. 18E are graphs illustrating the current-voltage measured in samples with the n-type contact layer having a thickness of 30 nm;

FIG. 19A, FIG. 19B, FIG. 19C, FIG. 19D, FIG. 19E and FIG. 19F are graphs illustrating the current-voltage measured in samples with the n-type contact layer having a thickness of 20 nm; and

FIG. 20A, FIG. 20B and FIG. 20C are graphs illustrating the current-voltage measured in samples with the n-type contact layer having a thickness of 10 nm.

### DETAILED DESCRIPTION

Embodiments which will be described below with reference to the accompanying drawings can be implemented singly or in combination with other embodiments. But this is not intended to limit the present invention to a certain embodiment, and it should be understood that all changes, modifications, equivalents or replacements within the spirits and scope of the present invention are included. Especially, any of functions, features, and/or embodiments can be implemented independently or jointly with other embodiments. Accordingly, it should be noted that the scope of the invention is not limited to the embodiments illustrated in the accompanying drawings.

Terms such as first, second, etc., may be used to refer to various elements, but, these element should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings.

Hereinafter, embodiments of the present invention will be described in detail with reference to the accompanying drawings.

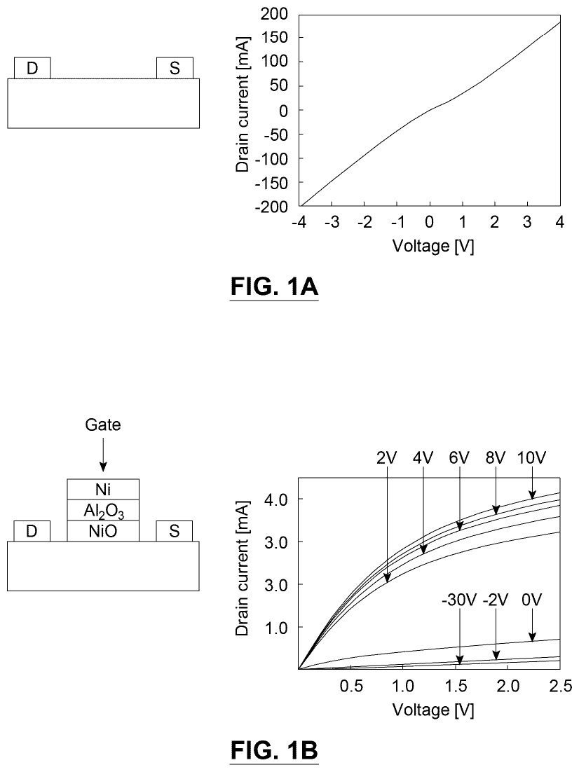

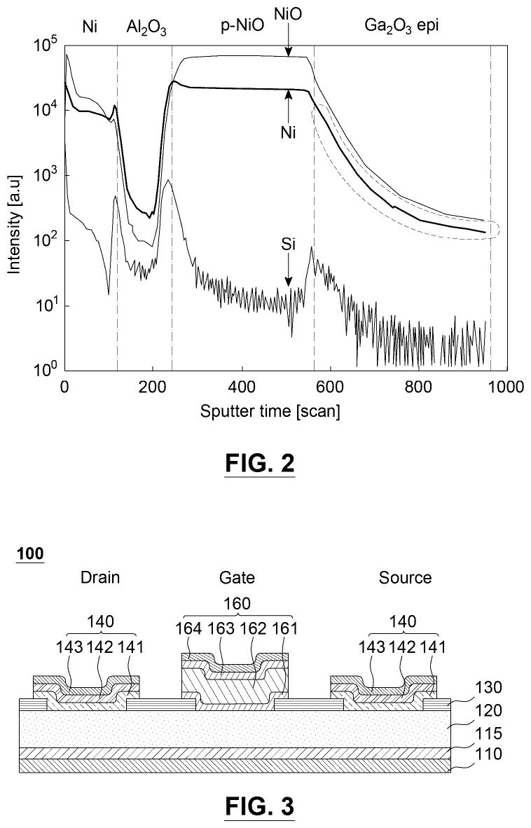

FIG. 1a and FIG. 1b exemplarily illustrate change in channel properties caused by nickel oxide, and FIG. 2 exemplarily illustrate change in channel properties caused by nickel oxide after gate is formed.

FIG. 1a shows current measurements after forming a source electrode and a drain electrode on an n-type gallium oxide epitaxial layer, and FIG. 1b shows current measurements after forming a gate in the structure illustrated in FIG. 1a. Referring to FIG. 1a, the current change due to a source-drain voltage change measured in the absence of the gate is substantially linear. When the source-drain voltage is about 2.5V, the current is measured to be about 105 mA. Meanwhile, referring to FIG. 1b, after the gate is formed, the current due to the source-drain voltage change varies non-linearly depending on a voltage applied to the gate. When the voltage applied to the gate is 10V and the source-drain voltage is about 2.5V, the current is measured to be about 4.14 mA, reducing to about 1/25 of the current measured before the gate is formed. This means that the gate will cause a channel resistance to increase.

The reason the gate affects the channel resistance is due to the diffusion of the metal that forms the gate electrode. FIG. 2 is a Secondary Ion Mass Spectrometry graph for a device formed in FIG. 1b, showing only detection curves for Ni, NiO, and Si, and omitting detection curves for other materials. When p-type NiO and n-type gallium oxide epitaxial layer are pn heterojunction, an intrinsic depletion region is formed in the n-type gallium oxide epitaxial layer. The n-type gallium oxide epitaxial layer is doped with a high concentration of n-type dopant and has low resistance, and the channel formed near the surface is blocked by the depletion region when no gate voltage is applied, so no current flows. Since the nickel diffused from p-type NiO into the channel is a p-type dopant, the resistance of a nickel diffusion region including the channel increases. The dotted line shows that nickel diffuses to the bottom surface of the n-type gallium oxide epitaxial layer, although the detection intensity decreases with increasing distance from the pn heterojunction.

Hereinafter, a gallium oxide semiconductor device that prevents changes in resistance of the entire channel or changes the resistance of a portion of the channel will be described.

FIG. 3 exemplarily illustrates a gallium oxide semiconductor device.

Referring to FIG. 3, the gallium oxide semiconductor device 100 may include a gallium oxide substrate 110, a gallium oxide buffer layer 115, an n-type gallium oxide epitaxial layer 120, an insulating layer 130, and source electrode/drain electrodes 141, 142, 143 (collectively referred to as 140), and gate electrodes 161, 162, 163, 164 (collectively referred to as 160).

The gallium oxide substrate 110 may be formed of single crystal β-gallium oxide β-Ga₂O₃ doped with an n-type dopant, for example, Fe, and the unintentionally doped (UID) gallium oxide buffer layer 115 may be formed on the gallium substrate 110. The thickness of the gallium oxide substrate 110 may be about 510 μm, and the thickness of the gallium oxide buffer layer 115 may be about 0.2 μm.

The n-type gallium oxide epitaxial layer 120 may be β-gallium oxide doped with the n-type dopant grown on the gallium oxide buffer layer 115. The n-type dopant may be, for example, silicon (Si), and the concentration of the n-type dopant may be about 2.7×10¹⁸ cm⁻³. The thickness of the n-type gallium oxide epitaxial layer 120 may be about 0.5 μm.

The insulating layer 130 may be formed by depositing silicon oxide SiO₂ on the n-type gallium oxide epitaxial layer 120, and may define a source/drain region and a gate region corresponding to the source electrode/drain electrode 140 and the gate electrode 160. The source/drain region and the gate region are regions where the n-type gallium oxide epitaxial layer 120 is exposed by etching the insulating layer 130. The insulating layer 130 deposited on the n-type gallium oxide epitaxial layer 120 may function as a field plate. The thickness of the insulating layer 130 may be about 0.7 μm.

The source electrode and drain electrode 140 may have the same stacked structure and may be formed in the source/drain region defined by the insulating layer 130. For example, the n-type contact layer 141 in contact with the n-type gallium oxide epitaxial layer 120 may be formed by depositing ITO (indium tin oxide), the first electrode layer 142 may be formed by depositing Ti, and the second electrode layer 143 may be formed by depositing Au sequentially. The n-type contact layer 141 may have a thickness of about 20 nm, the first electrode layer 142 may have a thickness of about 142 nm, and the second electrode layer 143 may have a thickness of about 50 nm.

The gate electrode 160 may include a diffusion barrier layer 161, a p-type nickel oxide layer 162, a dielectric layer 163, and a gate electrode layer 164 sequentially stacked in the gate area defined by the insulating layer 130. For example, the diffusion barrier layer 161 may be formed by depositing aluminum oxide Al₂O₃ on the n-type gallium oxide epitaxial layer 120, the p-type nickel oxide layer 162 may be formed by depositing nickel oxide NiOx on the diffusion barrier layer 161, the dielectric layer 163 may be formed by depositing aluminum oxide Al₂O₃ on the p-type nickel oxide layer 162, and the gate electrode layer 164 may be formed by depositing nickel Ni on the dielectric layer 163. The p-type nickel oxide layer 162 may have a thickness of about 250 nm, the dielectric layer 163 may have a thickness of about 50 nm, and the gate electrode layer 164 may have a thickness of about 100 nm.

The diffusion barrier layer 161 may be formed at a thickness that prevents diffusion of nickel from the p-type nickel oxide layer 162 to the n-type gallium oxide epitaxial layer 120 while allowing the pn heterojunction to form between the n-type gallium oxide epitaxial layer 120 and the p-type nickel oxide layer 162. For example, the diffusion barrier layer 161 may be deposited to a thickness of about 2 Å to about 100 Å. The diffusion barrier layer 161 may also be applied to the recessed gate electrode 180 (see FIG. 8). In the gate electrode 160 or the recessed gate electrode 180, the diffusion barrier layer 161 prevents the dopant concentration variation in the n-type gallium oxide epitaxial layer 120 from occurring, so that the channel as a whole can be maintained at low resistance.

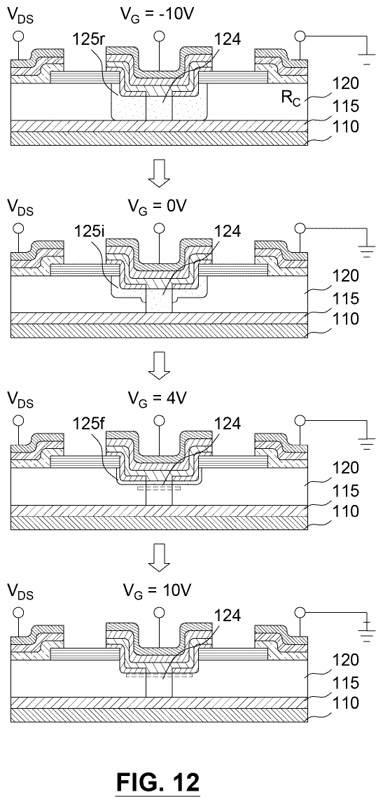

A pn heterojunction may be formed by the n-type gallium oxide epitaxial layer 120 and the p-type nickel oxide layer 162. A depletion region (see FIG. 12) may be formed in the n-type gallium oxide epitaxial layer 120 along the pn heterojunction, and the depletion region may be expanded or contracted depending on the gate voltage. Meanwhile, the dielectric layer 163 can minimize the generation of gate leakage current when the gate voltage increases.

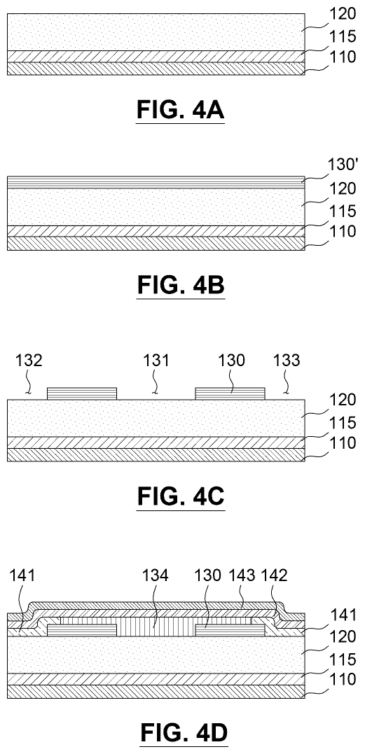

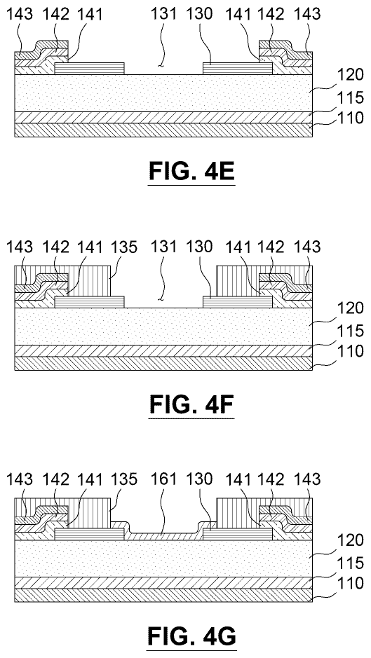

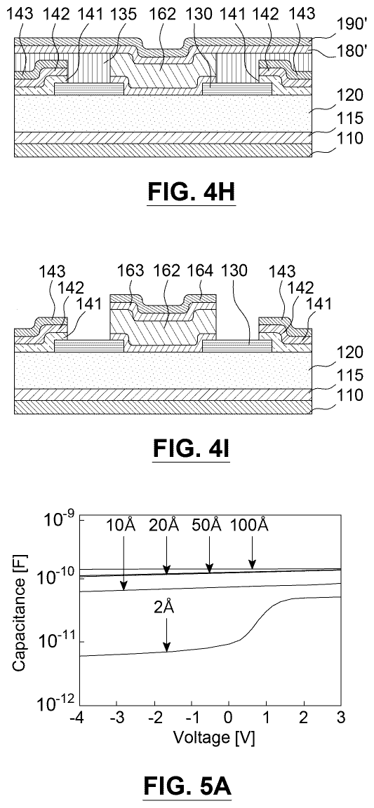

FIG. 4A, FIG. 4B, FIG. 4C, FIG. 4D, FIG. 4E, FIG. 4F, FIG. 4G, FIG. 4H and FIG. 4I exemplarily illustrate a process for manufacturing the gallium oxide semiconductor device.

In FIG. 4A, the n-type gallium oxide epitaxial layer 120 may be epitaxially formed on the gallium oxide buffer layer 115. Prior to forming the n-type gallium oxide epitaxial layer 120, foreign matters on the n-type gallium oxide substrate 110 on which the gallium oxide buffer layer 115 is formed may be removed by cleaning and plasma treatment. For example, the n-type gallium oxide epitaxial layer 120 may be formed by epitaxially growing β-gallium oxide doped with silicon Si at a concentration of about 2.7×10¹⁸ cm⁻³ to a thickness of about 0.5 μm. The n-type gallium oxide epitaxial layer 120 may be formed, for example, by Halide vapor phase epitaxy (HVPE), Metalorganic chemical vapor deposition (MOCVD), Mist CVD, Molecular Beam Epitaxy (MBE), Pulsed laser deposition (PLD), etc.

In FIG. 4B, a silicon oxide layer 130′ is formed on an upper surface of the n-type gallium oxide epitaxial layer 120. The silicon oxide layer 130′ may be formed by depositing silicon oxide SiO₂ to a thickness of about 0.7 μm by chemical vapor deposition or spin coating.

In FIG. 4C, the insulating layer 130 defining the gate region 131 and the source/drain regions 132 and 133 are formed by etching the silicon oxide layer 130′. A photoresist layer may be deposited on an upper surface of the silicon oxide layer 130′. The photoresist layer may be deposited by spin coating the photoresist on the silicon oxide layer 130′ and then soft baking it. Next, a photoresist mask may be formed by removing the photoresist in the regions where the gate region 131 and source/drain regions 132 and 133 are to be defined from the photoresist layer. Next, the insulating layer 130 may be formed by etching the silicon oxide layer 130′ exposed by the photoresist mask. The etching gases may be O₂ and C₄F₈ and may be supplied to the chamber at a flow rate of approximately 1:9. The chamber pressure may be maintained at about 7 mTorr, and about 2 KW of power may be applied for about 1 minute. The etch rate of the silicon oxide layer 130′ may be about 0.23 μm/min. The buffer process of forming a gas atmosphere by injecting etching gas, the etching process of applying power, and the cooling process may be performed repeatedly. Next, the photoresist mask may be removed.

In FIG. 4D, source/drain electrodes 140 are formed in source/drain regions 132 and 133. A photoresist layer may be deposited on the upper surface of the n-type gallium oxide epitaxial layer 120 on which the insulating layer 130 is formed. Next, the photoresist layer formed in the source/drain regions 132 and 133 may be removed to form a photoresist mask 134 that exposes the source/drain regions 132, 133 and covers the gate region 131. Next, the n-type contact layer 141, the first electrode layer 142, and the second electrode layer 143 may be sequentially deposited by, for example, physical vapor deposition. The n-type contact layer 141 may have a thickness of about 20 nm, the first electrode layer 142 may have a thickness of about 142 nm, and the second electrode layer 143 may have a thickness of about 50 nm.

In FIG. 4E, the n-type contact layer 141, the first electrode layer 142, and the second electrode layer 143 deposited in areas other than the source/drain regions 132 and 133 are removed.

In FIG. 4F, a photoresist layer may be deposited on the upper surface of the n-type gallium oxide epitaxial layer 120 on which the source/drain electrodes 140 are formed. Through a photo and etching process, the photoresist layer formed in the gate region 131 may be removed to form a photoresist mask 135 with the gate region 131 exposed.

In FIG. 4G, the diffusion barrier layer 161 is formed in the gate region 131. The diffusion barrier layer 161 may be formed by depositing aluminum oxide to a thickness of about 2 Å to about 100 Å on the n-type gallium oxide epitaxial layer 120 of the gate region 131 by plasma enhanced atomic layer deposition (PEALD).

In FIG. 4H, the p-type nickel oxide layer 162, the dielectric layer 163, and the gate electrode layer 164 may be sequentially formed on the diffusion barrier layer 161.

The p-type nickel oxide layer 162 may be deposited to a thickness of about 250 nm on the upper surface of the diffusion barrier layer 161 formed in the gate region 131 by sputtering a nickel oxide target or a nickel target. Sputtering may be carried out in a mixed gas atmosphere of argon-oxygen. The flow rate of oxygen may be adjusted between about 0.0% and 23.0%, preferably between about 9.0% and 16.6%, the chamber pressure may be maintained at about 5 mTorr, and a power of about 142 W may be applied for about 90 minutes.

The dielectric layer 163 may be deposited with aluminum oxide Al₂O₃ on the p-type nickel oxide layer 162 to a thickness of about 50 nm by PEALD. The precursors are Al(CH₃)₃ and O₃, and the chuck temperature may be about 250 degrees.

The gate electrode layer 164 may be deposited to a thickness of about 100 nm on the dielectric layer 163 by sputtering a nickel target. Sputtering may be carried out in an argon atmosphere, the chamber pressure may be maintained at about 5 mTorr, and a power of about 100 W may be applied for about 8 minutes.

In FIG. 4I, the diffusion barrier layer 161, the p-type nickel oxide layer 162, the dielectric layer 163, and the gate electrode layer 164 deposited in areas other than the gate region 131 may be removed. Afterwards, a post annealing may be performed. Post annealing may be carried out at about 500 degrees for about 1 minute in an argon atmosphere with a pressure of about 100 mTorr.

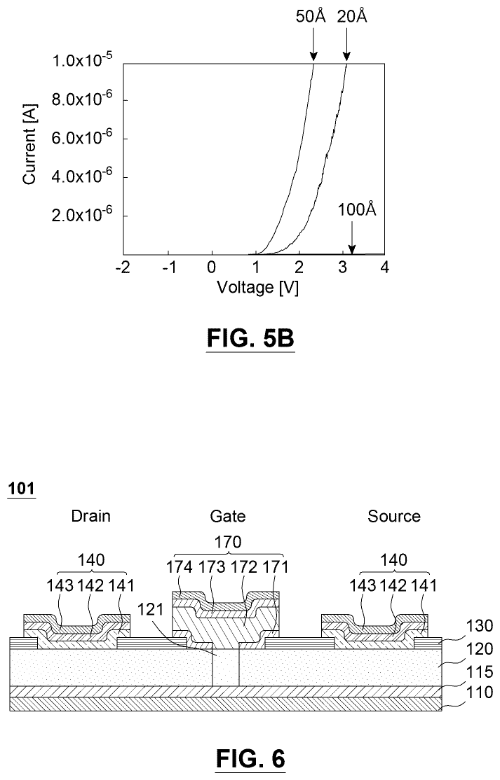

FIG. 5A and FIG. 5B show the electrical characteristics of the gallium oxide semiconductor device.

The diffusion barrier layer 161 of the gallium oxide semiconductor device 100 was formed with thicknesses of 2 Å, 10 Å, 20 Å, 50 Å, and 100 Å to measure the effect of thickness variation. Referring to FIG. 5A and FIG. 5B, a gate-source capacitance varies with the thickness of the diffusion barrier layer 161 formed of aluminum oxide between the n-type gallium oxide epitaxial layer 120 and the p-type nickel oxide layer 162. The diffusion barrier layer 161 should prevent diffusion of nickel into the n-type gallium oxide epitaxial layer 120 while enabling pn heterojunction between the n-type gallium oxide epitaxial layer 120 and the p-type nickel oxide layer 162. If the thickness of the diffusion barrier layer 161 increases, the effectiveness of the diffusion prevention increases, but it may hinder the formation of the pn heterojunction.

As shown in FIG. 5A, a tendency for capacitance to increase when forward bias is applied compared to when reverse bias is applied was found in the diffusion barrier layer 161 of all thicknesses. When reverse bias is applied, the capacitance due to the diffusion barrier layer 161 with a thickness of about 2 Å is about 1/10 of that of the diffusion barrier layer 161 with other thicknesses, but increases significantly when forward bias is applied, but still has a lower capacitance compared to other thicknesses. And, the capacitance due to the diffusion barrier layer 161 with a thickness of about 10 Å is relatively higher than 2 Å, but relatively lower than the capacitance of about 20 Å or more. On the other hand, there is no significant difference in capacitance due to the diffusion barrier layer 161 formed to a thickness of about 20 Å to about 50 Å. The capacitance due to the diffusion barrier layer 161 formed with a thickness of about 100 Å is relatively larger than other thicknesses in the reverse bias, and the difference decreases in the forward bias. In other words, when the thickness of the diffusion barrier layer 161 increases to about 20 Å or more, the depletion layer due to pn heterojunction decreases, and since the diffusion barrier layer 161 operates as a dielectric, the capacitance can be seen to increase.

Meanwhile, referring to FIG. 5B, the turn-on voltage also varies with the thickness of the diffusion barrier layer 161. The turn-on voltage of the gallium oxide semiconductor device 100 with the diffusion barrier layer 161 of about 20 Å and about 50 Å thickness has a turn-on voltage of about 1 V, whereas the gallium oxide semiconductor device 100 with the diffusion barrier layer 161 of about 100 Å thickness does not turn on. That is, the diffusion barrier layer 161 with a thickness of about 50 Å or less does not significantly affect the normal operation of the gallium oxide semiconductor device 100, while the diffusion barrier layer 161 thicker than 50 Å prevents the formation of a pn heterojunction.

FIG. 6 exemplarily illustrates a gallium oxide semiconductor device modified from the lateral gallium oxide transistor in FIG. 3.

Referring to FIG. 6, a gallium oxide semiconductor device 101 may include a gallium oxide substrate 110, a gallium oxide buffer layer 115, an n-type gallium oxide epitaxial layer 120, a counter doped region 121, an insulating layer 130, source/drain electrode 140, and gate electrode 170. The same description as in FIG. 3 will be omitted.

The gate electrode 170 may include a diffusion barrier layer 171, a p-type nickel oxide layer 172, a dielectric layer 173, and a gate electrode layer 174 sequentially stacked on the gate region 131 defined by the insulating layer 130. Unlike the diffusion barrier layer 161 of FIG. 3, which is formed over the entire n-type gallium oxide epitaxial layer 120 exposed through the gate region, a portion of the diffusion barrier layer 171 of FIG. 6 is removed so that a portion of a lower surface of the p-type nickel oxide layer 172 is in contact with the n-type gallium oxide epitaxial layer 120, and the remaining portion is in contact with the remaining unremoved diffusion barrier layer 171 that was not removed. The remaining unremoved diffusion barrier layer 171 may prevent nickel diffusion from the p-type nickel oxide layer 172 to the n-type gallium oxide epitaxial layer 120 and allows a pn heterojunction to be formed.

Meanwhile, the counter doped region 121 may be formed from the upper surface of the n-type gallium oxide epitaxial layer 120 toward the inside due to nickel diffused from the p-type nickel oxide layer 172 in contact with the n-type gallium oxide epitaxial layer 120. Due to the diffused nickel, the n-type dopant concentration of the counter doped region 121 becomes relatively lower than the n-type dopant concentration of the n-type gallium oxide epitaxial layer 120.

The depletion layer formed by pn heterojunction may be formed relatively wider in the counter doped region 121 than in the n-type gallium oxide epitaxial layer 120. Therefore, due to the counter doped region 121, a normally off gallium oxide semiconductor device 101 can be implemented.

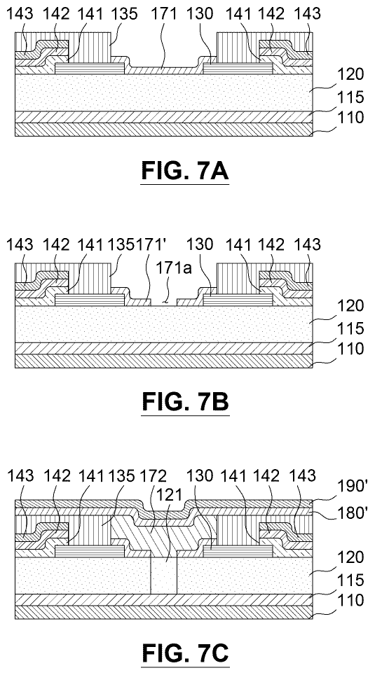

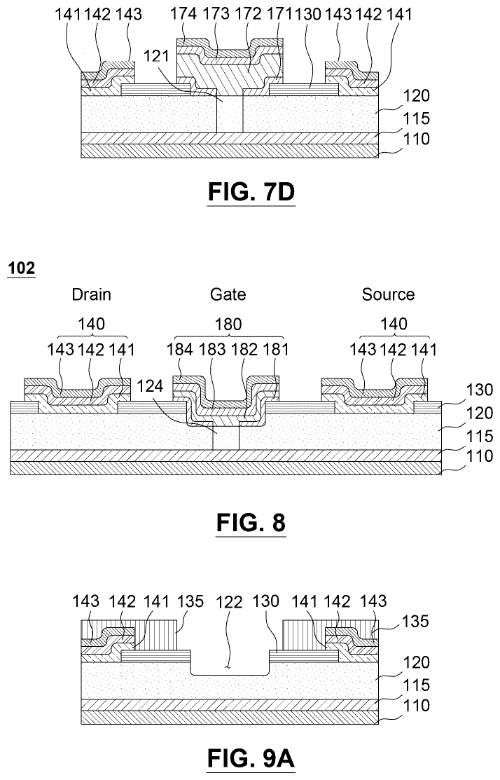

FIG. 7A, FIG. 7B, FIG. 7C and FIG. 7D exemplarily illustrate a process for manufacturing a lateral gallium oxide transistor shown in FIG. 6. Source/drain electrode formation is substantially the same as FIG. 4A through FIG. 4F, and further descriptions of the same will be omitted.

In FIG. 7A, a diffusion barrier layer 171′ is formed in the gate region 131. The diffusion barrier layer 171′ may be formed by depositing aluminum oxide to a thickness of about 2 Å to about 100 Å on the n-type gallium oxide epitaxial layer 120 of the gate region 131 by PEALD.

In FIG. 7B, an opening 171a defining the counter doped region 121 is formed in the diffusion barrier layer 171′. The opening 171a may be formed by removing a portion of the diffusion barrier layer 171′ to expose the upper surface of the n-type gallium oxide epitaxial layer 120. Depending on the horizontal width of the opening 171a, the width of the counter doped region 121 may be adjusted. In FIG. 7B, the opening 171a is formed in the center of the diffusion barrier layer 171, but considering the vertical depth of the channel formed in the n-type gallium oxide epitaxial layer 120, it may be formed closer to either of the source and drain electrodes. Meanwhile, only one opening 171a formed in the center is illustrated, but two or more openings 171a may be formed. For example, the first opening 171a may be formed close to the source electrode, and the second opening 171a may be formed close to the drain electrode.

In FIG. 7C, a p-type nickel oxide layer 172, a dielectric layer 173, and a gate electrode layer 174 are sequentially formed on the diffusion barrier layer 171 in which the opening 171a is formed.

The p-type nickel oxide layer 172 may be formed by depositing a nickel oxide target or a nickel target on the upper surface of the n-type gallium oxide epitaxial layer 120 exposed by the opening 171a and an upper surface of the diffusion barrier layer 171. A portion of a lower surface of the deposited p-type nickel oxide layer 172 forms the pn heterojunction with the n-type gallium oxide epitaxial layer 120 exposed by the opening 171a, and the remaining portion forms the pn heterojunction with the n-type gallium oxide epitaxial layer 120 not exposed by the opening 171a.

In FIG. 7D, the diffusion barrier layer 171′, the p-type nickel oxide layer 172, the dielectric layer 173, and the gate electrode layer 174 deposited in areas other than the gate region 131 are removed. Afterwards, a post annealing may be performed. Post annealing may be carried out at about 500 degrees for about 1 minute in an argon atmosphere with a pressure of about 100 m Torr.

FIG. 8 exemplarily illustrates a gallium oxide semiconductor device further modified from the gallium oxide semiconductor device in FIG. 3.

Referring to FIG. 8, the gallium oxide semiconductor device 102 may include a gallium oxide substrate 110, a gallium oxide buffer layer 115, an n-type gallium oxide epitaxial layer 120, a counter doped region 124, an insulating layer 130, source/drain electrodes 140, and a recessed gate electrode 180. The same description as in FIG. 3 will be omitted.

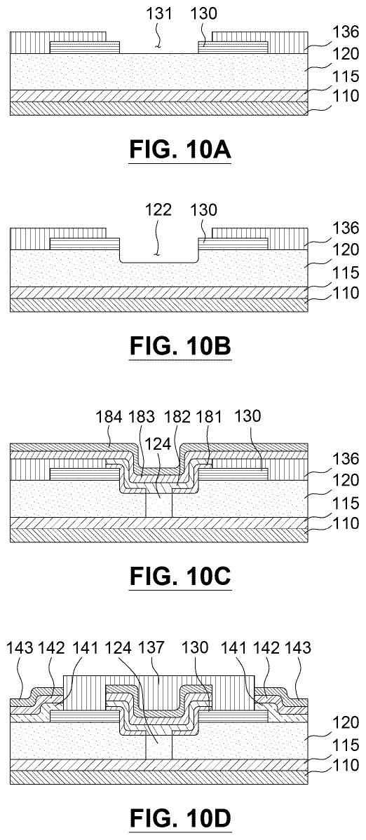

The recessed gate electrode may include a diffusion barrier layer 181, a p-type nickel oxide layer 182, a dielectric layer 183, and a gate electrode layer 184 stacked sequentially in a recessed gate trench 122 (see FIG. 10B) extending inwardly from the upper surface of the n-type gallium oxide epitaxial layer 120. The recessed gate trench 122 may be formed by etching the n-type gallium oxide epitaxial layer 120 of the gate region 131. Similar to FIG. 6, a portion of the diffusion barrier layer 181 is removed, such that a portion of the p-type nickel oxide layer 182 is in direct contact with the n-type gallium oxide epitaxial layer 120 to form the pn heterojunction, and the remaining portion of the p-type nickel oxide layer 182, with the remaining unremoved diffusion barrier layer 181 interposed therebetween, forms the pn heterojunction with the n-type gallium oxide epitaxial layer 120. The remaining unremoved diffusion barrier layer 181 may prevent nickel diffusion from the p-type nickel oxide layer 182 to the n-type gallium oxide epitaxial layer 120, allowing the pn heterojunction to be formed.

The diffusion barrier layer 181 may be formed on the bottom of the recessed gate trench 122, and may also be formed on the sidewall. The p-type nickel oxide layer 182 may be deposited on the diffusion barrier layer 181 and the n-type gallium oxide epitaxial layer 120, and may also be deposited on the sidewall of the recessed gate trench 122 depending on the slope of the sidewall. The dielectric layer 183 may be formed by depositing aluminum oxide Al₂O₃ on the p-type nickel oxide layer 182, and the gate electrode layer 184 may be formed by depositing nickel Ni on the dielectric layer 183. The thickness of the p-type nickel oxide layer 182 stacked on the bottom of the recessed gate trench 122 may be about 250 nm, the thickness of the dielectric layer 183 may be about 50 nm, and the thickness of the gate electrode layer 184 may be about 100 nm.

The depletion layer formed by the pn heterojunction may be formed relatively wider in the counter doped region 124 than in the n-type gallium oxide epitaxial layer 120. In particular, the distance between the counter doped region 124 of the gallium oxide semiconductor device 102 and the n-type gallium oxide substrate 110 (or the gallium oxide buffer layer 115) illustrated in FIG. 8 is shorter than the counter doped region 121 of the gallium oxide semiconductor device 101 illustrated in FIG. 6. Therefore, due to the counter doped region 124, a normally off gallium oxide semiconductor device 101 can be implemented.

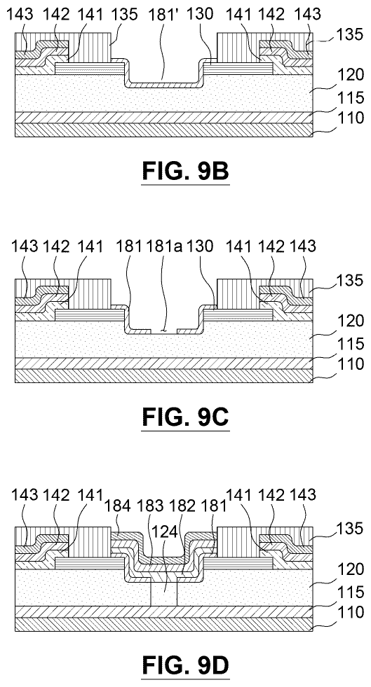

FIG. 9A, FIG. 9B, FIG. 9C and FIG. 9D exemplarily illustrate a process for manufacturing the gallium oxide semiconductor device shown in FIG. 8. Source/drain electrode formation is substantially the same as FIG. 4A through FIG. 4F, and further descriptions of the same will be omitted.

In FIG. 9A, the recessed gate trench 122 is formed in the gate region 131. The recessed gate trench 122 may be formed by etching the n-type gallium oxide epitaxial layer 120 exposed by an etch mask toward the inside. The etch mask may be an insulating layer 130, a photoresist mask 135, or a stack of the insulating layer 130 and the photoresist mask 135. The etching gases are N₂ and BCl₃, and may be supplied to the chamber at a flow rate of about 1:7. The chamber pressure may be maintained at about 5 mTorr, and a power of about 500 W may be applied for about 1 minute. The etch rate of the n-type gallium oxide epitaxial layer 120 may be about 0.057 μm/min, and the etch ratio between the n-type gallium oxide epitaxial layer 120 and the insulating layer 130 may be about 1:1.2. The formed recessed gate trench 122 may have a critical dimension CD of about 2 μm, a depth of about 0.7 μm, and a sidewall slope of about 45 degrees to about 70 degrees. The buffer process of forming a gas atmosphere by injecting etching gas, the etching process of applying power, and the cooling process may be performed repeatedly.

In FIG. 9B, a diffusion barrier layer 181′ is formed in the recessed gate trench 122. The diffusion barrier layer 181′ may be formed by depositing aluminum oxide to a thickness of about 2 Å to about 100 Å on the n-type gallium oxide epitaxial layer 120 on the bottom and/or sidewall of the recessed gate trench 122 by PEALD.

In FIG. 9C, an opening 181a defining the counter doped region 124 is formed in the diffusion barrier layer 181′. The opening 181a may be formed by removing a portion of the diffusion barrier layer 181′ to expose the upper surface of the n-type gallium oxide epitaxial layer 120. Depending on the horizontal width of the opening 181a, the width of the counter doped region 124 may be adjusted. In FIG. 9C, the opening 181a is formed in the center of the diffusion barrier layer 181, but considering the vertical depth of the channel formed in the n-type gallium oxide epitaxial layer 120, it may be formed closer to either of the source and drain electrodes. Meanwhile, only one opening 181a formed in the center is illustrated, but two or more openings 181a may be formed. For example, the first opening 181a may be formed close to the source electrode, and the second opening 181a may be formed close to the drain electrode.

In FIG. 9D, a p-type nickel oxide layer 182, a dielectric layer 183, and a gate electrode layer 184 are sequentially formed on the diffusion barrier layer 181 in which the opening 181a is formed.

The p-type nickel oxide layer 182 may be formed by depositing a nickel oxide target or a nickel target on the upper surface of the n-type gallium oxide epitaxial layer 120 exposed by the opening 181a and an upper surface of the diffusion barrier layer 181. A portion of a lower surface of the deposited p-type nickel oxide layer 182 forms the pn heterojunction with the n-type gallium oxide epitaxial layer 120 exposed by the opening 181a, and the remaining portion forms the pn heterojunction with the n-type gallium oxide epitaxial layer 120 not exposed by the opening 181a.

Subsequently, the diffusion barrier layer 181′, the p-type nickel oxide layer 182, the dielectric layer 183, and the gate electrode layer 184 deposited in areas other than the recessed gate trench 122 (or gate region 131) are removed, and a post annealing may be performed. Post annealing may be carried out at about 500 degrees for about 1 minute in an argon atmosphere with a pressure of about 100 mTorr.

FIG. 10A, FIG. 10B, FIG. 10C and FIG. 10D exemplarily illustrate an alternative process for manufacturing the gallium oxide semiconductor device shown in FIG. 8. The formation of the insulating layer 130 is substantially the same as FIG. 4A through FIG. 4C, and further description of the same will be omitted.

In FIG. 10A, a photoresist mask 136 is deposited to expose the gate region 131 and to cover the source/drain regions 132, 133.

In FIG. 10B, the n-type gallium oxide epitaxial layer 120 exposed by the etch mask is etched inward to form the recess gate trench 122.

In FIG. 10C, the gate electrode 180 is formed by sequentially stacking the diffusion barrier layer 181, the p-type nickel oxide layer 182, the dielectric layer 183, and the gate electrode layer 184 in the recess gate trench 122, and by removing the diffusion barrier layer 181, p-type nickel oxide layer 182, dielectric layer 183, and gate electrode layer 184 deposited in areas other than the recess gate trench 122 or gate region 131. Meanwhile, the counter doped region 124 is formed in the n-type gallium oxide epitaxial layer 120 by nickel diffused through the opening 181a.

In FIG. 10D, source/drain electrodes 140 are formed in source/drain regions 132, 133. The source/drain formation is substantially the same as FIG. 4A through FIG. 4E. Once the source/drain electrodes 140 are formed, post annealing may be performed.

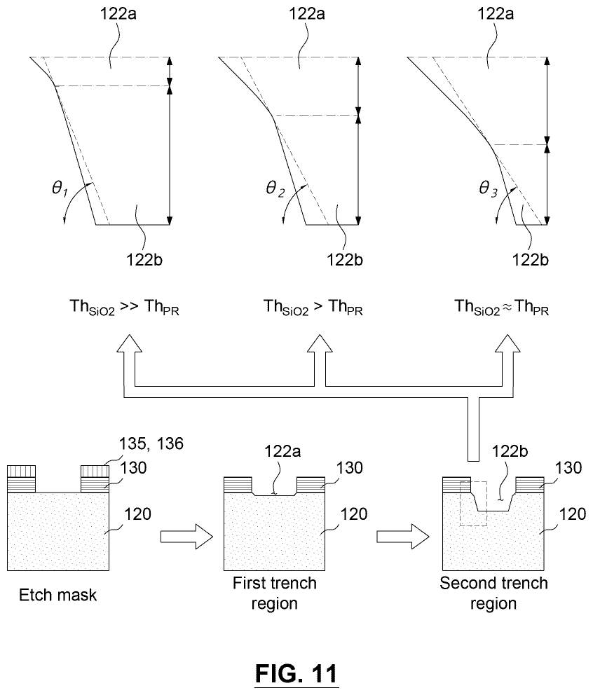

FIG. 11 exemplarily illustrates adjusting the sidewall slope of a recessed gate trench.

An etch mask is formed by etching the silicon oxide layer 130′ exposed by the photoresist mask 135 or 136.

Next, the first trench region 122a is formed by etching the n-type gallium oxide epitaxial layer 120 exposed by the insulating layer 130 and the photoresist mask 135 or 136 deposited on the insulating layer 130. The first trench region 122a is formed by the photoresist mask 135 or 136. Since the photoresist mask 135 or 136 is also etched at a constant rate, the thickness of the photoresist mask 135 or 136 can be adjusted according to the depth of the first trench region 122a.

Next, the second trench region 122b having sidewalls extending from the sidewalls of the first trench region 122a is formed with the insulating layer 130. The first trench region 122a and the second trench region 122b form the recessed gate trench 122.

The etch mask used to etch the recessed gate trench 122 may be selected from (i) the insulating layer 130 formed of silicon oxide, (ii) the photoresist mask 135 or 136, or (iii) the insulating layer 130 and the photoresist mask 135 or 136 of the same pattern deposited on top of the insulating layer 130. The sidewall slope of the recessed gate trench 122 may be adjusted depending on the type of etch mask. If the n-type gallium oxide epitaxial layer 120 is etched using only the insulating layer 130, the sidewall slope of the recessed gate trench 122 may be about 70 degrees. If the n-type gallium oxide epitaxial layer 120 is etched using only the photoresist mask 135 or 136, the sidewall slope of the recessed gate trench 122 may be about 45 degrees.

The sidewall slope from the top to the bottom of the first trench region 122a may be determined by the thickness of the photoresist mask 135 or 136, and the sidewall slope of the second trench region 122b may be determined by the combination of the side wall slope of the first trench region 122a and the insulating layer 130. Accordingly, when the insulating layer 130 and the photoresist mask 135 or 136 of the same pattern stacked on top of the insulating layer 130 are used as the etch mask, the sidewall slope of the recessed gate trench 122 can be adjusted in about 45 degrees and about 70 degrees.

FIG. 11 also illustrates the slope of the sidewall of the recessed gate trench when the thickness of the photoresist mask 135 or 136 is increased while maintaining the sum of the thickness of the photoresist mask 135 or 136 and the thickness of the insulating layer 130. The first trench region 122a formed by the photoresist mask 135 or 136 has sidewalls inclined at about 45 degrees due to the polymer generated by the photoresist. As the thickness of the photoresist increases, the depth of the first trench region 122a becomes deeper, and the depth of the second trench region 122b becomes shallower. When etching using the photoresist mask 135 or 136 is completed, then etching using the insulating layer 130 begins. During the etching process of the insulating layer 130, the sidewall inclined at about 45 degrees due to the polymer is also etched downwardly. As a result, the sidewall of the recessed gate trench 111 becomes closer to a curved surface as a whole. Therefore, the sidewall slopes θ1, θ2, and θ3 can be measured using the tangent line touching the curved surface. When the photoresist mask 135 or 136 have the thinnest thickness, the sidewall slope θ₁ approaches approximately 70 degrees, and when the insulating layer 130 has the thinnest thickness, the sidewall slope θ₃ approaches approximately 45 degrees.

FIG. 12 exemplarily illustrates the operation of a gallium oxide semiconductor device according to gate voltage, using the gallium oxide semiconductor device 102 shown in FIG. 8 as an example.

When the gate voltage V_{G} is about −10V, the depletion region 125r is formed to a significant depth in both the n-type gallium oxide epitaxial layer 120 and the counter doped region 124. The channel is formed in the n-type gallium oxide epitaxial layer 120 below the gate electrode 180 and can be blocked or conducted by the depletion region 125r formed in the n-type gallium oxide epitaxial layer 120 and the counter doped region 124 by the pn heterojunction. The depletion region 125r may be expanded or contracted depending on the gate voltage V_{G}.

When the gate voltage V_{G} is 0V, the depletion region 125i is formed deeper in the counter doped region 124 than in the n-type gallium oxide epitaxial layer 120. Since the n-type dopant concentration of the counter doped region 124 is lower than that of the n-type gallium oxide epitaxial layer 120, when the gate voltage is not applied, the intrinsic depletion region 125i caused by the pn heterojunction is wider (or deeper) in the counter doped region 124, thereby blocking the channel. This indicates that the gallium oxide semiconductor device is normally off.

When the gate voltage V_{G} becomes greater than 0V, the depletion region 125f rapidly shrinks and disappears. It can be seen that the channel is formed in the n-type gallium oxide epitaxial layer 120 below the gate electrode 180, and electrons are accumulated in the channel as the gate voltage V_{G} increases.

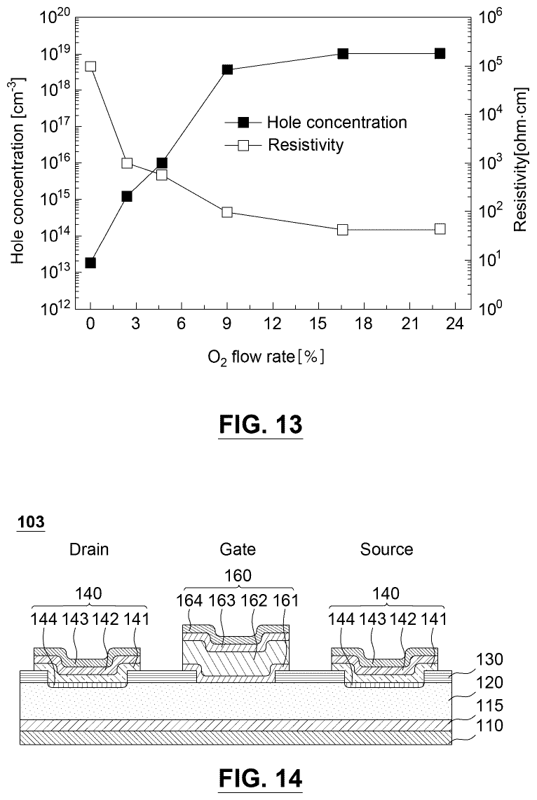

FIG. 13 is a graph illustrating the electrical characteristics of nickel oxide according to oxygen flow rate.

The hole concentration and resistivity of p-type nickel oxide can be adjusted depending on the oxygen flow rate during deposition. FIG. 13 shows the hole concentration and resistivity of the p-type nickel oxide layer deposited while adjusting the oxygen flow rate in Ar—O₂ mixed gas to about 0.0%, about 2.4%, about 4.7%, about 9.0%, about 16.6%, and about 23.0%, and Table 1 shows the process parameters and measured breakdown voltage according to each oxygen flow rate.

TABLE 1

| O₂ flow rate | 0.0% | 2.4% | 4.7% | 9.0% | 16.6% | 23.0% |
|---|---|---|---|---|---|---|
| process time | 37 | 66 | 85 | 89 | 90 | 92 |
| (Minutes) | | | | | | |
| Deposition | 8.1 | 4.5 | 3.5 | 3.4 | 3.3 | 3.2 |
| rate (nm/min) | | | | | | |
| Hole | 1.8 × 10¹³ | 1.2 × 10¹⁵ | 1.0 × 10¹⁶ | 3.7 × 10¹⁸ | 1.05 × 10¹⁹ | 1.03 × 10¹⁹ |
| concentration | | | | | | |
| (cm⁻³) | | | | | | |
| Resistivity | 98,400 | 994 | 564 | 96 | 42 | 44 |
| (ohm · cm) | | | | | | |

Referring to FIG. 13, as the oxygen flow rate increases, the hole concentration increases while the resistivity decreases. The hole concentration in the oxygen flow rate range of about 9.0% to about 23.0% is significantly increased over the hole concentration in the oxygen flow rate range of about 0.0% to about 4.7%, and the resistivity in the oxygen flow rate range of about 16.6% to about 23.0% is significantly decreased over the resistivity in the oxygen flow rate range of about 0.0% to about 9.0%. Therefore, the oxygen flow rate can be adjusted in the range of about 9.0% to about 23.0%, and preferably in the range of about 16.6% to about 23.0%.

FIG. 14 exemplarily illustrates a gallium oxide semiconductor device still further modified from the gallium oxide semiconductor device in FIG. 3.

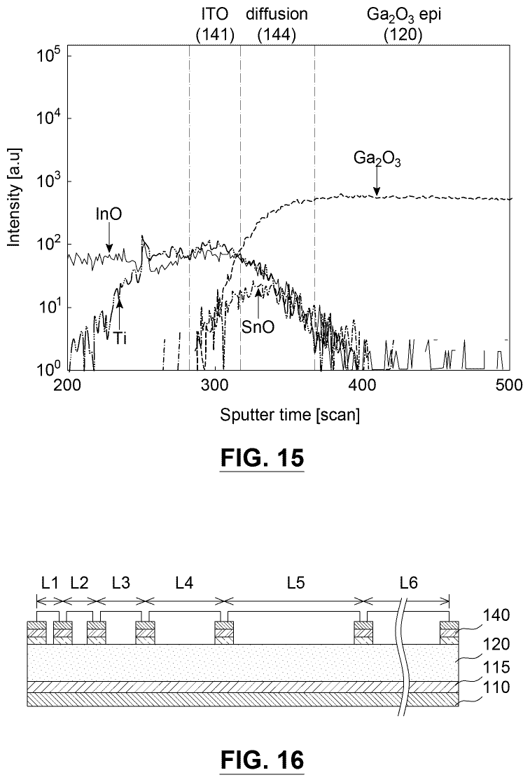

Referring to FIG. 15, the gallium oxide semiconductor device 103 may include a gallium oxide substrate 110, a gallium oxide buffer layer 115, an n-type gallium oxide epitaxial layer 120, an insulating layer 130, source electrode/drain electrodes 140, and a gate electrode 160. Descriptions of the same parts as those in FIG. 3 will be omitted.

The source electrode and drain electrode 140 may have the same stacked structure and may be formed in the source/drain region defined by the insulating layer 130. For example, the n-type contact layer 141 in contact with the n-type gallium oxide epitaxial layer 120 may be formed by depositing ITO (indium tin oxide), the first electrode layer 142 may be formed by depositing Ti, and the second electrode layer 143 may be formed by depositing Au sequentially. The ITO consists of about 90 wt % In₂O₃ and about 10 wt % SnO₂. The thickness of the n-type contact layer 141 may be about 10 nm to about 30 nm, preferably about 10 nm to approximately 20 nm, most preferably about 10 nm, the thickness of the first electrode layer 142 may be about 50 nm, and the thickness of the second electrode layer 143 may be about 100 nm. The n-type contact layer 141, the first electrode layer 142, and the second electrode layer 143 may be formed by physical vapor deposition, for example, sputtering.

The diffusion layer 144 is an n+ region extending from the heterojunction between the n-type contact layer 141 and the n-type gallium oxide epitaxial layer 120 to the inside of the n-type gallium oxide epitaxial layer 120 by SnO diffused from the n-type contact layer 141 to the n-type gallium oxide epitaxial layer 120 by a post annealing, and improves band alignment between the first and second electrode layers 142, 143 and the n-type gallium oxide epi layer 120. In general, the Fermi level of the first electrode layer 142 has a larger offset than the conduction band of the n-type gallium oxide epitaxial layer 120. The diffusion layer 144 can reduce the discontinuity of the conduction band between the first electrode layer 142 and the n-type gallium oxide epitaxial layer 120. The Schottky barrier height between the gallium oxide and the metal is about 0.9 eV to about 1.45 eV, but when ITO with a bandgap of about 3.5 eV is introduced as an intermediate layer between the gallium oxide and Ti, the ITO conduction band remains substantially the same as Ti while the Schottky barrier height with the gallium oxide is reduced to about 0.32 eV. That is, the diffusion layer 144 can reduce a contact resistance to improve ohmic contact characteristics, similar to silicide formed in silicon at silicon-metal bonding. On the other hand, since the diffusion layer 144 is formed by the post annealing, an additional implantation for forming the n+ region can be omitted.

FIG. 15 is a graph showing SIMS results for the source/drain electrode structure illustrated in FIG. 14.

Referring to FIG. 15, the n-type contact layer 141, the first electrode layer 142, and the second electrode layer 143 are sequentially deposited on the n-type gallium oxide epitaxial layer 120, and SIMS analysis result of the post-annealing samples is shown. It can be seen that, by the post-annealing, InO and SnO from the n-type contact layer 141 are diffused into the n-type gallium oxide epitaxial layer 120 from the heterojunction between the n-type contact layer 141 and the n-type gallium oxide epitaxial layer 120. Ti from the first electrode layer 142 is also diffused into the n-type contact layer 141 and the n-type gallium oxide epitaxial layer 120.

FIG. 16 exemplarily illustrates a sample for measuring changes in ohmic contact resistance occurred by the diffusion layer.

Referring to FIG. 16, the sample may include a gallium oxide substrate 110 formed of a single crystal β-gallium oxide (β-Ga₂O₃) doped with an n-type dopant, for example, Fe, an UID (Unintentionally doped) gallium oxide buffer layer 115 formed on the gallium oxide substrate 100, an n-type gallium oxide epitaxial layer 120 which is β-gallium oxide epitaxially grown and doped with Si on the gallium oxide buffer layer 115, and a plurality of electrodes 140 formed on the n-type gallium oxide epitaxial layer 120. The concentration of Si may be about 2.7×10¹⁸ cm⁻³. The thickness of the electrically insulating gallium oxide substrate 110 may be about 510 μm, the thickness of the gallium oxide buffer layer 115 may be about 0.2 μm, and the thickness of the n-type gallium oxide epitaxial layer 120 may be about 0.5 μm.

The electrode 140 includes an n-type contact layer formed of ITO having a thickness of about 0.1 μm to about 0.3 μm, a first electrode layer formed of Ti having a thickness of approximately 0.05 μm, and a second electrode layer formed of Ti having thickness of approximately 0.1 μm. The distance between the plurality of electrodes 140 is L1 to L6, L1 is about 5 μm, L2 is about 10 μm, L3 is about 20 μm, L4 is about 40 μm, L5 is about 80 μm, and L6 is about 160 μm.

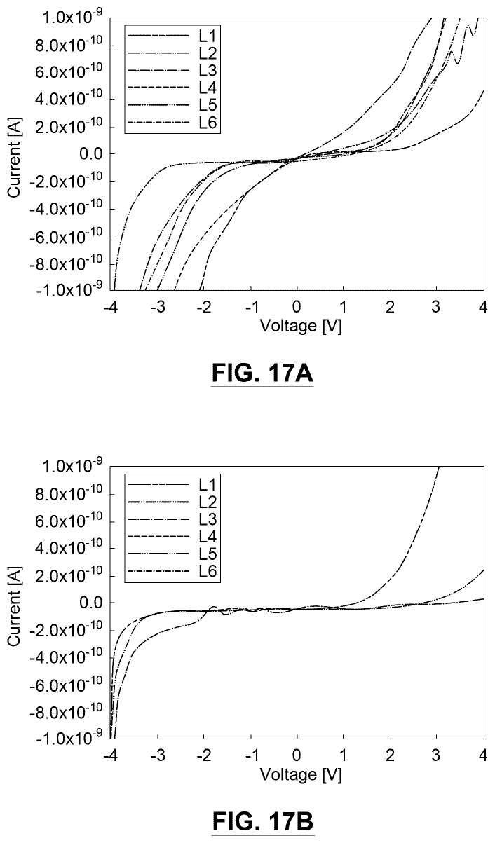

The sample having the above-described structure is used to derive the measurements illustrated in FIGS. 17A to 20C below.

FIG. 17A and FIG. 17B are graphs illustrating the current-voltage measured in samples with the n-type contact layer having a thickness of 300 nm.

FIG. 17A is a current-voltage graph measured on a sample that has not been annealed (hereinafter, referred as “as fabricated”), and FIG. 17B is a current-voltage graph measured in a sample that has been post-annealed. The contact resistance Rc measured in the as fabricated sample was about 189 MΩ, and no significant difference was found from the contact resistance measured in the post annealed sample. The post-annealing was performed in an N₂ atmosphere, with a pressure of about 1 Torr, a temperature of about 500° C., and a time of about 30 seconds.

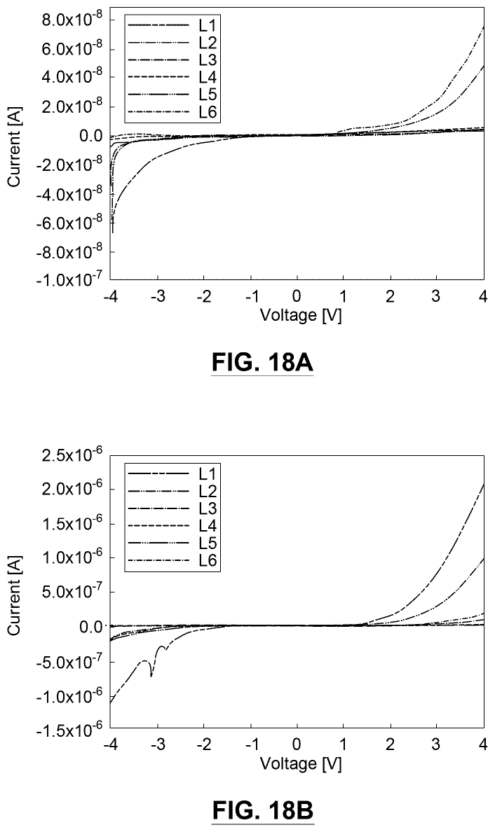

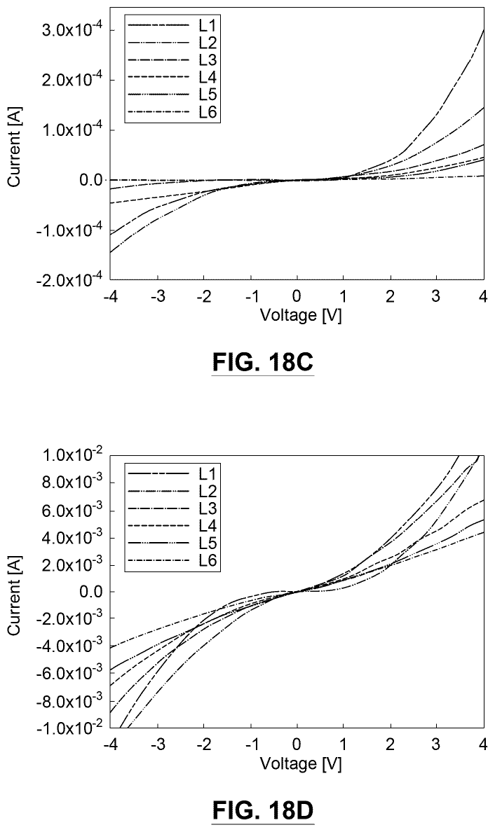

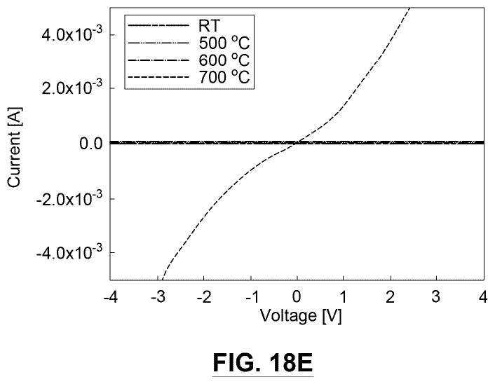

FIGS. 18A to 18E are graphs illustrating the current-voltage measured in samples with the n-type contact layer having a thickness of 30 nm.

FIG. 18A is a current-voltage graph measured on the as fabricated sample that has not been post-annealed, and FIGS. 18B-18D are current-voltage graphs measured on post-annealed samples. The post-annealing was carried out in an N₂ atmosphere with the same pressure of about 1 Torr and time of about 30 seconds, but with different temperatures. FIG. 18B is a current-voltage measured in the sample annealed at about 500° C., FIG. 18C is a current-voltage measured in the sample annealed at about 600° C., and FIG. 18D is a current-voltage measured in the sample annealed at about 700° C. Comparing FIG. 18B and FIG. 18C with FIG. 18A, it can be seen that the effect of the post-annealing is insignificant, whereas compared with FIG. 18D, the amount of current between electrodes is greatly increased by the post-annealing. FIG. 18E shows the current-voltage measured between electrodes with a spacing of about 20 μm in order to compare the effect on temperature.

It can be seen from the result of the post-annealing of the samples on which the n-type contact layer having a thickness of about 30 nm is formed, that the surface resistance and the ohmic contact resistance decrease as the annealing temperature increases. It can be seen that a contact resistivity ρc calculated from the current-voltage measured in the sample annealed at about 600° C. was about 1,190 mΩ·cm², and the contact resistivity ρc calculated from the voltage measured in the sample annealed at about 700° C. was approximately 69 mΩ·cm², which was significantly improved as compared with the contact resistivity 189 MΩ calculated from FIG. 17B.

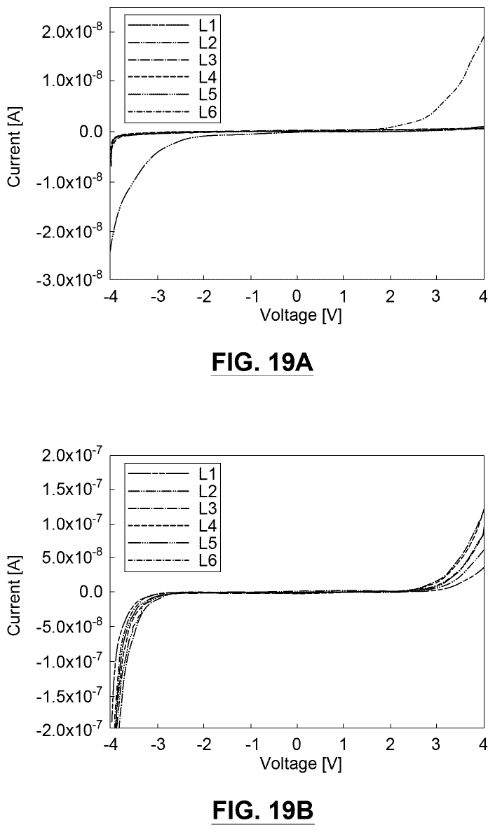

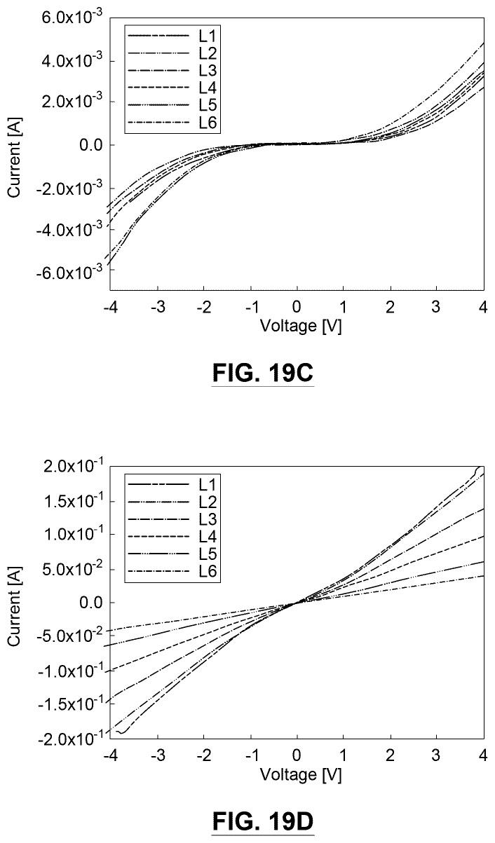

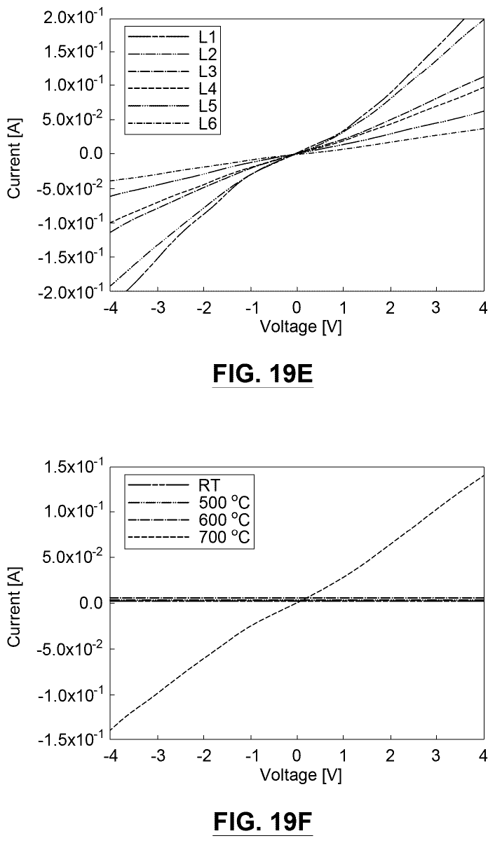

FIGS. 19A to 19F are graphs illustrating the current-voltage measured in samples with the n-type contact layer having a thickness of 20 nm.

FIG. 19A is a current-voltage graph measured on the as fabricated sample that has not been post-annealed, and FIGS. 19B-19E are current-voltage graphs measured on post-annealed samples. The post-annealing was carried out in an N₂ atmosphere with the same pressure of about 1 Torr and time of about 30 seconds, but with different temperatures. FIG. 19B is a current-voltage measured in the sample annealed at about 500° C., FIG. 19C is a current-voltage measured in the sample annealed at about 600° C., FIG. 19D is a current-voltage measured in the sample annealed at about 700° C., and FIG. 19E is a current-voltage measured in the sample annealed at about 800° C. Comparing FIG. 19B and FIG. 19C with FIG. 19A, it can be seen that the effect of the post-annealing is insignificant, whereas compared with FIG. 19D and FIG. 19E, the amount of current between electrodes is greatly increased by the post-annealing. FIG. 19F shows the current-voltage measured between electrodes with a spacing of about 20 μm in order to compare the effect according to temperature.

It can be seen from the result of the post-annealing of the samples on which the n-type contact layer having a thickness of about 20 nm is formed, that the surface resistance and the ohmic contact resistance decrease as the annealing temperature increases. The contact resistivity ρc calculated from the current-voltage measured in the sample annealed at about 600° C. was about 119 mΩ·cm², the contact resistivity ρc calculated from the voltage measured in the sample annealed at about 700° C. was approximately 1.3 mΩ·cm², and the contact resistivity ρc calculated from the power-voltage determined in the sample annealed at about 800° C. was around 1.4 mΩ·cm², indicating that the contact resistance was significantly improved when compared with the contact resistance 189 MΩ calculated from FIG. 17B, and indicating that there is a correlation between the post-annealing temperature and the thickness of the diffusion layer

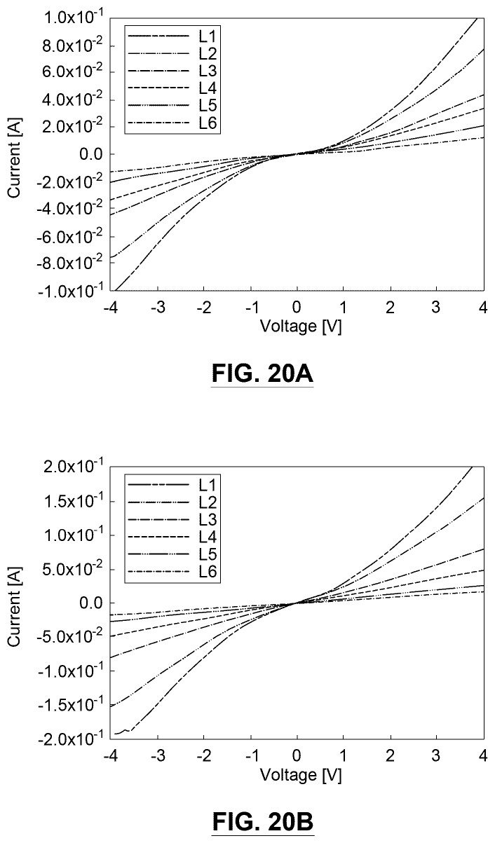

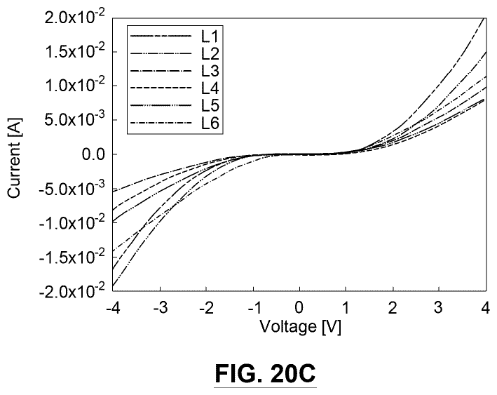

FIGS. 20A to 20C are graphs illustrating the current-voltage measured in samples with the n-type contact layer having a thickness of 10 nm.

FIGS. 20A to 20C are current-voltage graphs measured on post-annealed samples. The post heat treatment was carried out in an N₂ atmosphere with the same pressure of about 1 Torr and time of about 30 seconds, but with different temperatures. FIG. 20A is a current-voltage measured in the sample annealed at about 700° C., FIG. 20B is a current-voltage measured in the sample annealed at about 800° C., and FIG. 20C is a current-voltage measured in sample annealed at about 900° C. In all of FIGS. 20A to 20C, it can be seen that the amount of current between the electrodes was greatly increased by the post-annealing. When FIG. 20B and FIG. 20C are compared, it can be seen that when the post-annealing temperature exceeds about 800° C., the current actually decreases.

From the result of the post-annealing of the samples on which the n-type contact layer having a thickness of about 10 nm is formed, it can be seen that the surface resistance and the ohmic contact resistance decrease as the temperature increases to around 800° C., but the surface resistance and ohmic contact resistance increase when the temperature exceeds about 800° C. It can be seen that the contact resistance pc calculated from the current-voltage measured in the sample annealed at about 700° C. is about 2.1 mΩ·cm², the contact specific resistance pc determined from the current-voltage measured in the sample annealed at about 800° C. is approximately 0.69 mΩ·cm², and the contact specific resistance pc determined from the voltage measured in the sample annealed at about 900° C. is around 40.6 mΩ·cm². Compared with the contact resistance 189 MΩ calculated from FIG. 17B, it can be seen that there is a significant improvement in the contact resistance, and from this result, there is also a correlation between the post-annealing temperature and the thickness of the n-type contact layer.

The above description of the invention is exemplary, and those skilled in the art can understand that the invention can be modified in other forms without changing the technical concept or the essential feature of the invention. Therefore, it should be understood that the above-mentioned embodiments are exemplary in all respects, but are not definitive.

The scope of the invention is defined by the appended claims, not by the above detailed description, and it should be construed that all changes or modifications derived from the meanings and scope of the claims and equivalent concepts thereof are included in the scope of the invention.

What is claimed is:

1. A gallium oxide semiconductor device, comprising:
an n-type gallium oxide epitaxial layer epitaxially grown on a gallium oxide substrate;
an n-type contact layer formed of indium tin oxide on the n-type gallium oxide epitaxial layer;
a metal electrode layer formed on the n-type contact layer; and
a diffusion layer extending from a heterojunction between the n-type gallium oxide epitaxial layer and the n-type contact layer toward the n-type gallium oxide epitaxial layer,
wherein the diffusion layer is formed by diffusing the n-type contact layer into the n-type gallium oxide epitaxial layer by a post-annealing.

2. The gallium oxide semiconductor device of claim 1, wherein the n-type contact layer has a thickness of 10 nm to 30 nm.

3. The gallium oxide semiconductor device of claim 1, wherein a post-annealing temperature is in a range between 700° C. and 800° C.

4. The gallium oxide semiconductor device of claim 1 further comprising:
an insulating layer defining a gate region and an electrode region on the n-type gallium oxide epitaxial layer;
a p-type nickel oxide layer deposited on the gate region;
a dielectric layer deposited on the p-type nickel oxide layer; and
a gate electrode layer deposited on the dielectric layer,
wherein the n-type contact layer is formed in the electrode region.

5. The gallium oxide semiconductor device of claim 4 further comprising:
a diffusion barrier layer, interposed between the n-type gallium oxide epitaxial layer exposed in the gate region and the p-type nickel oxide layer.

6. The gallium oxide semiconductor device of claim 5, wherein the diffusion barrier layer is formed by depositing aluminum oxide in a thickness of 2 Å to 50 Å.

7. The gallium oxide semiconductor device of claim 5 further comprising:
a counter doped region formed within the n-type gallium oxide epitaxial layer below the diffusion barrier layer and having a lower concentration than the n-type gallium oxide epitaxial layer.

8. The gallium oxide semiconductor device of claim 7, wherein the diffusion barrier layer has an opening exposing the n-type gallium oxide epitaxial layer,
wherein the counter doped region is formed by nickel diffusing from the p-type nickel oxide layer through the opening into the n-type gallium oxide epitaxial layer.

9. A method of manufacturing gallium oxide semiconductor device, comprising:
forming an n-type contact layer of indium tin oxide on an n-type gallium oxide epitaxial layer epitaxially grown on an n-type gallium oxide substrate;
forming a metal electrode layer on the n-type contact layer; and
forming a diffusion layer extending from a heterojunction between the n-type gallium oxide epitaxial layer and the n-type contact layer toward the n-type gallium oxide epitaxial layer by a post-annealing.

10. The method of claim 9, wherein the n-type contact layer has a thickness of 10 nm to 30 nm.

11. The method of claim 9, wherein a post-annealing temperature is in a range between 700° C. and 800° C.

12. The method of claim 9, wherein the forming an n-type contact layer of indium tin oxide on an n-type gallium oxide epitaxial layer epitaxially grown on an n-type gallium oxide substrate comprises:
forming an insulating layer defining a gate region and an electrode region on the n-type gallium oxide epitaxial layer;
depositing a diffusion barrier layer on the n-type gallium oxide epitaxial layer exposed in the gate region;
depositing a p-type nickel oxide layer on the diffusion barrier layer;
depositing a dielectric layer on the p-type nickel oxide layer;
depositing a gate electrode layer on the dielectric layer; and
forming the n-type contact layer on the n-type gallium oxide epitaxial layer exposed in the electrode region.

13. The method of claim 12, wherein the diffusion barrier layer is deposited at a thickness such that a pn heterojunction is formed between the p-type nickel oxide layer and the n-type gallium oxide epitaxial layer while preventing nickel diffusion from the p-type nickel oxide layer to the n-type gallium oxide epitaxial layer.

14. The method of claim 12 further comprising forming an opening exposing the n-type gallium oxide epitaxial layer in the diffusion barrier layer.
